(19) United States
(12) Patent Application Publication
(10) Pub. No.: US 2020/0152922 A1
(43) Pub. Date: May 14, 2020

(54) MANUFACTURING METHOD OF FILM LAYER, DISPLAY SUBSTRATE AND MANUFACTURING METHOD THEREOF AND DEVICE THEREOF

(71) Applicants: Chengdu Boe Optoelectronics Technology Co., Ltd., Chengdu (CN); Boe Technology Group Co., Ltd., Beijing (CN)

(72) Inventors: Shilong Wang, Beijing (CN); Zhiliang Jiang, Beijing (CN); Minghao Gao, Beijing (CN)

(21) Appl. No.: 16/534,172

(22) Filed: Aug. 7, 2019

(30) Foreign Application Priority Data
Nov. 14, 2018 (CN) 201811353103.0

(51) Int. Cl. H01L 51/56; H01L 51/52; H01L 33/56

(52) U.S. Cl. CPC H01L 51/56; H01L 2933/005; H01L 33/56; H01L 51/5253

(57) ABSTRACT

A manufacturing method of a film layer, a display substrate and a manufacturing method thereof, and a device for manufacturing a display substrate are provided. The manufacturing method of a film layer includes: forming an organic layer on a substrate, in which the organic layer includes a flat portion and a slope portion around the flat portion; and heating the flat portion to cause a material of the flat portion to flow toward the slope portion, such that a thickness of a portion of the slope portion close to the flat portion is identical to a thickness of the flat portion to increase a size of the flat portion in a direction parallel to the substrate.

The present application claims priority of Chinese Patent Application No. 201811353103.0, filed on Nov. 14, 2018, the disclosure of which is incorporated herein by reference in its entirety as part of the present application.

### TECHNICAL FIELD

At least one embodiment of the present disclosure relates to a manufacturing method of a film layer, a display substrate and a manufacturing method thereof, and a device for manufacturing a display substrate.

### BACKGROUND

In a thin film encapsulation process, an important function of an organic layer in a thin film encapsulation layer is planarization. The degree of planarization of the organic layer manufactured by an inkjet printing method affects the display quality of a display device.

### SUMMARY

At least one embodiment of the present disclosure provides a manufacturing method of a film layer, a display substrate and a manufacturing method thereof, and a device for manufacturing a display substrate.

At least one embodiment of the present disclosure provides a manufacturing method of a film layer, comprising: forming an organic layer on a substrate, in which the organic layer comprises a flat portion and a slope portion around the flat portion; and heating the flat portion to cause a material of the flat portion to flow toward the slope portion, such that a thickness of a portion of the slope portion close to the flat portion is identical to a thickness of the flat portion to increase a size of the flat portion in a direction parallel to the substrate.

In some examples, the organic layer has a material that is capable of flowing in a heated state.

In some examples, the organic layer is formed by an inkjet printing method.

In some examples, forming the organic layer by the inkjet printing method comprises: printing an organic material on the substrate, and the flat portion and slope portion being formed during a leveling process of the organic material.

In some examples, heating the flat portion comprises: heating only the flat portion, or heating the flat portion at a temperature higher than a temperature at which the slope portion is heated.

In some examples, heating only the flat portion comprises: heating the flat portion by a heat source, in which an orthographic projection of a region of the organic layer heated by the heat source on the substrate is located in an orthographic projection of the flat portion before being heated on the substrate.

In some examples, a thickness of the flat portion is uniform.

In some examples, during heating, a size of an orthographic projection of the organic layer on the substrate does not change.

At least one embodiment of the present disclosure provides a manufacturing method of a display substrate, comprising: forming a plurality of light-emitting display units on a base substrate; and forming the organic layer by using the manufacturing method according to any one of the above examples on a side of the plurality of light-emitting display units away from the base substrate.

In some examples, the organic layer is a thin film encapsulation layer.

In some examples, the display substrate comprises a display region and a peripheral region surrounding the display region, and the plurality of light-emitting display units are formed in the display region. Before the organic layer is heated, an orthographic projection of the flat portion on the base substrate is located within an orthographic projection of the display region on the base substrate, an orthographic projection of the slope portion on the base substrate overlaps with the orthographic projection of the display region on the base substrate; after the organic layer is heated, the orthographic projection of the slope portion on the base substrate does not overlap with the orthographic projection of the display region on the base substrate.

In some examples, a temperature for heating the flat portion is not more than 85° C.

At least one embodiment of the present disclosure provides a display substrate formed by the above-mentioned manufacturing method of the display substrate.

At least one embodiment of the present disclosure provides a device for manufacturing the above-mentioned display substrate, comprising: an abutment, configured to support the base substrate; and a heating plate, on a side of the abutment facing the base substrate. An orthographic projection of the heating plate on the abutment is located within an orthographic projection of the flat portion before being heated on the abutment.

In some example, the heating plate and the base substrate are vacuum-adsorbed on a surface of the abutment.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1A is a schematic diagram of a planar structure of a display panel mother board;

FIG. 1B is a partial cross-sectional diagram of a display panel shown in FIG. 1A taken along line AB;

FIG. 2A is a schematic process step diagram of a manufacturing method of a film layer according to an embodiment of the present disclosure;

FIGS. 2B and 2C are schematic flow charts of a manufacturing method of a film layer according to an embodiment of the present disclosure;

FIG. 3A is a schematic process step diagram of a manufacturing method of a display substrate according to an embodiment of the present disclosure;

FIGS. 3B and 3C are schematic flow charts of a manufacturing method of a display substrate according to an embodiment of the present disclosure; and

FIG. 4 is a partial schematic structural diagram of a device for manufacturing a display substrate according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

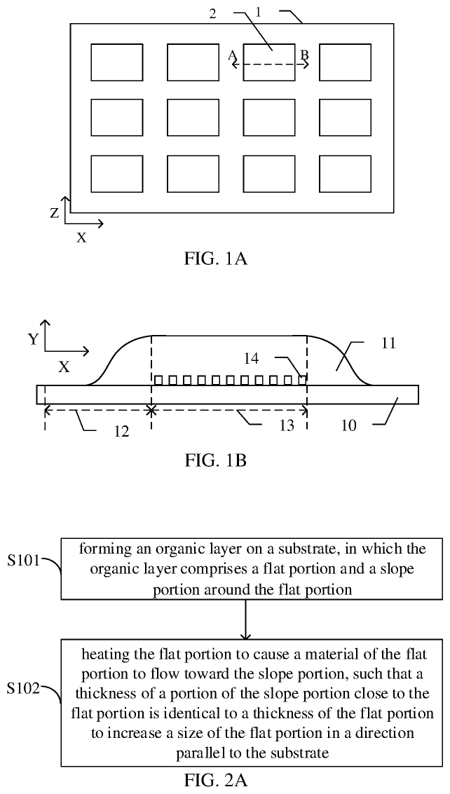

FIG. 1A is a schematic diagram of a planar structure of a display panel mother board, and FIG. 1B is a partial cross-sectional diagram of a display panel shown in FIG. 1A taken along line AB. As shown in FIG. 1A and FIG. 1B, a display panel mother board 1 comprises a plurality of display panels 2, each display panel 2 comprises a base substrate 10, a plurality of light-emitting display units 14 disposed on the base substrate 10, and a thin film encapsulation layer disposed on a side of the light-emitting display units 14 away from the base substrate 10. The display panel 2 comprises a display region 13 for display and a peripheral region 12 surrounding the display region 13, the thin film encapsulation layer covers the display region 13 and at least a part of the peripheral region 12, and the thin film encapsulation layer comprises an organic layer 11 formed by an inkjet printing method.

In research, the inventors of the present application found that in a thin film encapsulation process of the display device, the organic layer is generally formed by the inkjet printing method. During the inkjet printing process, due to the characteristics of organic materials (surface tension and viscosity of the organic material, and the infiltration relationship between the organic material and the base substrate), the organic layer may have problems in leveling, for example, an edge of the organic layer has low leveling property, resulting in a long climbing distance of a slope portion of the organic layer. The leveling refers to a process in which the organic material gradually shrinks to a minimum area due to the action of the surface tension of the organic material after the organic material is coated to the base substrate and before the organic material is solidified into a film. The power of leveling is the surface tension of the organic material, that is, the force of self-shrinkage of the organic material, which is the main force that makes the surface of the organic material smooth and flat. In addition, the viscosity of the organic material will affects the leveling of the organic material, and the longer the organic material maintains a low viscosity liquid state, the better the leveling of coating a film.

In order to make the thickness of the organic layer located in the display region uniform, the position of the slope portion needs to be designed inside a frame, to ensure that the position where the slope portion of the organic layer is located outside the display region. However, the long climbing distance of the slope portion is not conductive to the design of a narrow frame.

In addition, the leveling problem during the inkjet printing process not only causes display unevenness (display Mura), reduces display quality, but also is detrimental to the thickness reduction of the organic layer. In a case where the thickness of the organic layer is thinned, the slope portion formed during the inkjet printing process may cause the thickness of the organic layer to be more uneven, that is, the thinner the thickness of the organic layer is, the more serious the leveling problem is, thereby being disadvantageous for the thinning of the thickness of the display device including the above organic layer, and at the same time, also adversely affecting the bending property of the display device.

At least one embodiment of the present disclosure provides a manufacturing method of a film layer, a display substrate and a manufacturing method thereof, and a device for manufacturing a display substrate. The manufacturing method of the film layer comprises: forming an organic layer on a substrate, the organic layer comprising a flat portion and a slope portion around the flat portion; and heating the flat portion to cause a material of the flat portion to flow toward the slope portion, such that a thickness of a portion of the slope portion close to the flat portion is identical to a thickness of the flat portion to increase a size of the flat portion in a direction parallel to the substrate. The manufacturing method of the film layer provided by the embodiment of the present disclosure can reduce the size of the slope portion in the direction parallel to the substrate by converting a portion of the slope portion close to the flat portion into a portion of the flat portion, thereby facilitating to reduce the thickness of the organic layer while ensuring the thickness uniformity of the organic layer.

The manufacturing method of a film layer, the display substrate and the manufacturing method thereof, and the device for manufacturing the display substrate provided by the embodiments of the present disclosure will be described below with reference to the accompanying drawings.

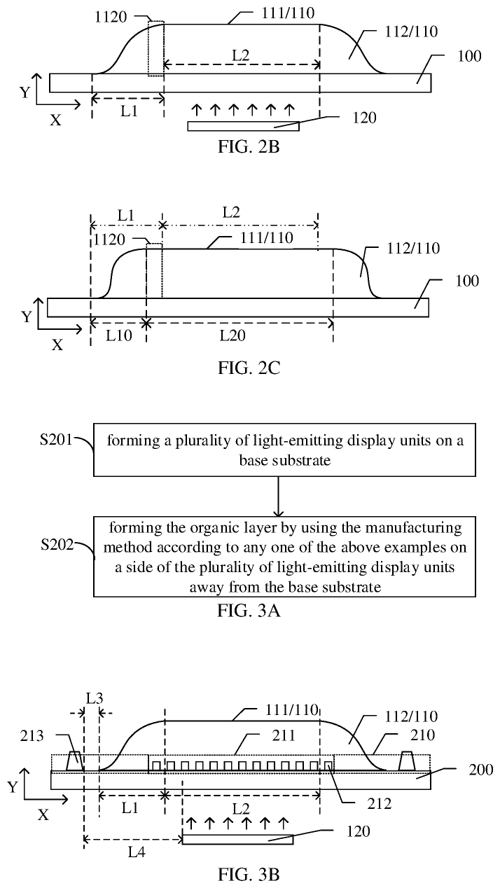

An embodiment of the present disclosure provides a manufacturing method of a film layer, FIG. 2A is a schematic process step diagram of a manufacturing method of a film layer according to an embodiment of the present disclosure, and FIGS. 2B and 2C are schematic flow charts of a manufacturing method of a film layer according to an embodiment of the present disclosure. As shown in FIG. 2A, the manufacturing method of the film layer provided by the embodiment of the present disclosure comprises the following steps.

S101: forming an organic layer on a substrate, in which the organic layer comprises a flat portion and a slope portion around the flat portion.

For example, as shown in FIG. 2B, the organic layer 110 is formed by an inkjet printing method.

For example, as shown in FIG. 2B, forming the organic layer 110 by the inkjet printing method comprises: printing an organic material on the substrate 100, and the flat portion 111 and slope portion 112 are formed during a leveling process of the organic material.

The flat portion 111 described above indicates that a surface of the portion of the organic material away from the substrate 100 is a flat surface substantially parallel to a main plane (a plane perpendicular to a Y direction in FIG. 2B) of the substrate 100, that is, a thickness of the flat portion 111 in the Y direction is uniform. The slope portion 112 indicates that a distance between a surface of the portion of the organic material away from the substrate 100 and the substrate 100 gradually decreases in a direction from a side close to the flat portion 111 toward a side away from the flat portion 111.

For example, as shown in FIG. 2B, in the direction parallel to the substrate 100, such as an X direction shown in the drawing, a size of an orthographic projection of the flat portion 111 on the substrate 100 is L2, and a size of an orthographic projection of the slope portion 112 on the substrate 100 is L1. The size of the orthographic projection of the slope portion 112 on the substrate 100 in the X direction is a climbing distance of the organic layer 110, that is, a distance from an edge of the organic layer 110 to a portion away from the edge to reach a target height, and therefore, the climbing distance of the slope portion 112 is L1. The target height may be a thickness range of the organic layer 110. For example, the target height may be micron order, for example, may be 2-15 μm, but the present disclosure is not limited thereto. In the inkjet printing process, the size L1 of the portion of the slope portion 112 that is in contact with the substrate 100 is relatively large due to factors such as the surface tension and the viscosity of the organic material, and the infiltration relationship between the organic material and the substrate.

S102: heating the flat portion to cause a material of the flat portion to flow toward the slope portion, such that a thickness of a portion of the slope portion close to the flat portion is identical to a thickness of the flat portion to increase a size of the flat portion in a direction parallel to the substrate.

For example, the organic layer has a material that is capable of flowing in a case where the material of the organic layer is heated, that is, during a heating process, the organic material included in the organic layer 110 flows in a certain direction.

For example, the material of the organic layer 110 may be an organic matter such as a resin, but the present disclosure is not limited thereto. The resin may be, for example, a thermosetting resin, and the thermosetting resin comprises, for example, an epoxy resin, but the present disclosure is not limited thereto. The resin may be, for example, a thermoplastic resin, and the thermoplastic resin comprises, for example, an acrylic (PMMA) resin, but the present disclosure is not limited thereto.

As shown in FIG. 2B and FIG. 2C, the surface tension of the organic material decreases as the temperature rises, and therefore, in a case where the flat portion is heated, the surface tension of the organic material included in the flat portion 111 may decrease, leading to a case that the surface tension of the organic material included in the flat portion 111 is lower than the surface tension of the organic material included in the slope portion 112. According to the Marangoni effect, the fluid spontaneously flows from a region with low tension to a region with high tension, the flowing power of the fluid is a surface tension gradient, that is, a liquid with low surface tension will move to a region with high surface tension along the gradient. Thus, the organic material included in the flat portion 111 is heated such that the surface tension of the organic material included in the flat portion 111 is lower than the surface tension of the organic material included in the slope portion 112, so the organic material included in the flat portion 111 can spontaneously flow to the position where the slope portion 112 is located, thereby increasing the height of a partial slope portion 1120 close to the flat portion 111, that is, a height difference between the partial slope portion 1120 close to the flat portion 111 and the flat portion 111 is compensated (the height of the partial slope portion 1120 is substantially the same as the height of the flat portion 111). The partial slope portion 1120 is converted into a portion of the flat portion 111, thereby increasing the size of the flat portion 111 in the direction parallel to the substrate 110, and reducing the size of the slope portion 112 in the direction parallel to the substrate 110, that is, decreasing the climbing distance of the slope portion 112.

For example, as shown in FIG. 2B and FIG. 2C, a size of the orthographic projection of the heated flat portion 111 on the substrate 100 in the X direction is L20, and a size of the orthographic projection of the slope portion 112 on the substrate 100 in the X direction is L10. The flat portion 111 and the slope portion 112 shown in FIG. 2B are respectively a flat portion and a slope portion before being heated, and the flat portion 111 and the slope portion 112 shown in FIG. 2C are respectively a flat portion and a slope portion after being heated. In the present embodiment, the flat portion and the slope portion of the organic layer before and after being heated are both referred to as the flat portion 111 and the slope portion 112. In fact, the size of the flat portion after being heated in the direction parallel to the substrate is larger than the size of the flat portion before being heated in the direction parallel to the substrate, and the climbing distance of the slope portion of the organic layer after being heated is smaller than the climbing distance of the slope portion of the organic layer before being heated.

For example, when the flat portion 111 is heated, the organic material included in the flat portion 111 flows toward the position where the slope portion 112 is located, thereby increasing the size of the orthographic projection of the flat portion 111 on the substrate 110 in the X direction, that is, L20 is larger than L2.

For example, as shown in FIG. 2B and FIG. 2C, when the flat portion 111 is heated, the organic material included in the flat portion 111 flows toward the position where the slope portion 112 is located, so that the height of the partial slope portion 1120 close to the flat portion 111 before the organic layer being heated is increased to be almost the same as the height of the flat portion 111, and thus, the partial slope portion 1120 is converted into a portion of the flat portion 111 to increase the size of the flat portion 111 from L2 to L20.

For example, as shown in FIG. 2B and FIG. 2C, during the heating process, the size of the orthographic projection of the organic layer 110 on the substrate 100 does not change, that is, before the organic layer is heated, the size of the orthographic projection of the organic layer 110 on the substrate 100 in the X direction is L2+2*L1; and after the organic layer is heated, the size of the orthographic projection of the organic layer 110 on the substrate 100 in the X direction is L20+2*L10, and L2+2*L1 is substantially the same as L20+2*L10. Because the size of the orthographic projection of the flat portion 111 on the substrate 100 in the X direction is increased during heating process, the size of the orthographic projection of the slope portion 112 on the substrate 100 in the X direction is reduced, that is, L10 is smaller than L1.

For example, as shown in FIG. 2B and FIG. 2C, after the partial slope portion 1120 is converted into a portion of the flat portion 111, the size of the slope portion 112 is reduced from L1 to L10.

FIG. 2B and FIG. 2C show changes in the sizes of the flat portion 111 and the slope portion 112 in the X direction before and after the organic layer being heated, and the X direction may be any direction parallel to the substrate 100.

As can be seen from the process of manufacturing the organic layer shown in FIGS. 2B and 2C, the climbing distance of the slope portion of the organic layer is shortened, and the leveling property is ameliorated.

For example, as shown in FIG. 2B, in an example of the present embodiment, heating the flat portion 111 comprises heating only the flat portion 111. For example, a heat source can be used to only heat the flat portion 111, and an orthographic projection of a region, which is heated by the heat source, of the organic layer 110 on the substrate 100 is located within the orthographic projection of the flat portion 111 on the substrate 100.

For example, as shown in FIG. 2B, the heat source 120 may be a heating plate, and the orthographic projection of the heating plate on the substrate 100 is located within the orthographic projection of the flat portion 111 before being heated on the substrate 100. For example, a material of the heating plate comprises, but is not limited to, a metal material such as copper, aluminum, iron, or the like, and an alloy thereof, and may also comprise an organic conductive material, an inorganic conductive material, or the like. For example, the heating plate can be connected to a heating wire or a heating rod to increase the temperature of the heating plate to achieve to heat the flat portion by the heating plate. The embodiment is not limited thereto, and the heat source may also be a laser, an ultrasonic wave, or the like, as long as the flat portion can be heated so as to lower the surface tension of the flat portion.

For example, FIG. 2B schematically shows a case that the heat source 120 is located on a side of the substrate 100 away from the organic layer 110, however the embodiment is not limited thereto, and the heat source may also be located on a side of the organic layer away from the substrate.

For example, in another example of the present embodiment, heating the flat portion 111 comprises heating the flat portion 111 at a temperature higher than a temperature at which the slope portion 112 is heated. In the present example, although both the flat portion 111 and the slope portion 112 may be heated, the temperature at which the flat portion 111 is heated must be higher than the temperature at which the slope portion 112 is heated, thereby ensuring that during heating, the surface tension of the organic material included in the flat portion 111 is lower than the surface tension of the organic material included in the slope portion 112, so that the organic material included in the flat portion 111 spontaneously flows to the position where the slope portion 112 is located, and thus, the thickness of a portion of the slope portion 112 close to the flat portion 111 is the same as the thickness of the flat portion 111 to increase the size of the flat portion 111 in the direction parallel to the substrate 100 and to reduce the climbing distance of the slope portion 112.

The manufacturing method of the film layer provided by the embodiment of the present disclosure can effectively improve the leveling performance of the organic layer, thereby reducing the climbing distance of the slope portion. In addition, in a case where the film layer is thinned, because the climbing distance of the slope portion is reduced, the probability of uneven thickness of the organic layer can be effectively reduced, which is advantageous for reducing the thickness of the organic layer while ensuring the thickness uniformity of the organic layer.

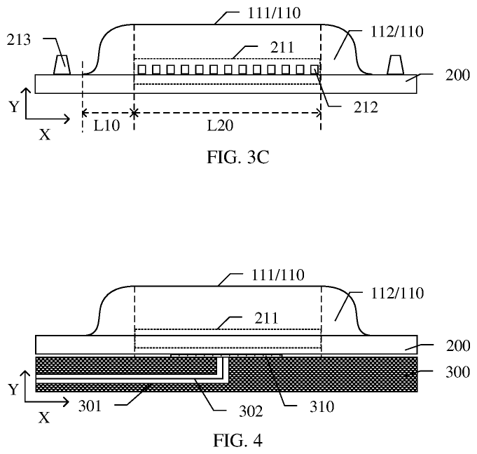

Another embodiment of the present disclosure provides a manufacturing method of a display substrate, FIG. 3A is a schematic process step diagram of a manufacturing method of a display substrate according to an embodiment of the present disclosure, and FIGS. 3B and 3C are schematic flow charts of a manufacturing method of a display substrate according to an embodiment of the present disclosure. As shown in FIG. 3A, the manufacturing method of a display substrate provided by an embodiment of the present disclosure comprises the following steps.

S201: forming a plurality of light-emitting display units on a base substrate.

For example, as shown in FIG. 3B, the plurality of light-emitting display units 212 are formed on the base substrate 200 to form a display region 211, a region other than the display region 211 is a peripheral region 210, and the peripheral region 210 surrounds the display region 211.

For example, the light-emitting display unit 212 may be an organic light-emitting display unit or an inorganic light-emitting display unit.

S202: forming the organic layer by using the manufacturing method according to any one of the above examples on a side of the plurality of light-emitting display units away from the base substrate.

For example, the organic layer 110 provided in the embodiment is an organic layer in a thin film encapsulation layer.

For example, as shown in FIG. 3B and FIG. 3C, in a case where the flat portion 111 in the organic layer 110 is heated, the surface tension of an organic material included in the flat portion 111 may be decreased, leading to a case that the surface tension of the organic material included in the flat portion 111 is lower than the surface tension of the organic material included in the slope portion 112, so that the organic material included in the flat portion 111 spontaneously flows to the position where the slope portion 112 is located, thereby compensating the height difference between a partial slope portion close to the flat portion 111 and the flat portion 111. The partial slope portion is converted into a portion of the flat portion 111, thereby increasing the size of the flat portion 111 in a direction parallel to the substrate 110 and decreasing the climbing distance of the slope portion 112.

For example, after the organic layer is heated, an orthographic projection of the display region 211 on the base substrate 200 is located within an orthographic projection of the flat portion 111 on the base substrate 200. By manufacturing the organic layer through the abovementioned manufacturing method, the consistency of thicknesses of the organic layer respectively located in an intermediate region and an edge region of the display region can be improved, thereby reducing the probability of generating the display mura. Moreover, the reduction of the climbing distance of the slope portion in the organic layer can facilitate the thinning of the organic layer, that is, facilitate the bending property of the display device.

For example, as shown in FIG. 3B and FIG. 3C, before the organic layer is heated, an orthographic projection of the flat portion 111 on the base substrate 200 is located within an orthographic projection of the display region 211 on the base substrate 200, and an orthographic projection of the slope portion 112 on the base substrate 200 overlaps with the orthographic projection of the display region 211 on the base substrate 200; after the organic layer is heated, the orthographic projection of the slope portion 112 on the base substrate 200 does not overlap with the orthographic projection of the display region 211 on the base substrate 200.

For example, as shown in FIG. 3B, before the flat portion 111 is heated by the heat source 120, the orthographic projection of the display region 211 on the base substrate 200 overlaps with both of the orthographic projection of the flat portion 111 on the base substrate 200 and the orthographic projection of the slope portion 112 on the base substrate 200, and the orthographic projection of the display region 211 on the base substrate 200 is entirely located within an orthographic projection of the organic layer 110 on the base substrate 200. For example, in the X direction parallel to the base substrate 200, the size of the display region 211 is larger than L2, and the size of the display region 211 is smaller than L1+L2.

For example, FIG. 3C schematically shows that, after heating the organic layer 110, the orthographic projection of the flat portion 111 on the base substrate 200 substantially coincides with the orthographic projection of the display region 211 on the base substrate 200. For example, along the Y direction, the orthographic projection of an edge of the slope portion 112 close to the flat portion 111 on the base substrate 200 is aligned with the orthographic projection of an edge of the display region 211 on the base substrate 200. The embodiment comprises but is not limited thereto. For example, after heating the organic layer, the orthographic projection of the display region on the base substrate may also be located within the orthographic projection of the flat portion on the base substrate.

The organic layer in the thin film encapsulation process has a flattening effect, in order to prevent display unevenness (display mura) caused by the unevenness of the thickness of the organic layer, the flat portion of the organic layer needs to cover the display region as completely as possible, and therefore, the position where the slope portion of the organic layer is located needs to be designed inside the frame.

In the thin film encapsulation process shown in FIG. 1B, the organic layer shown in FIG. 1B is directly formed by an inkjet printing method. Compared with the process of directly forming an organic layer that completely covers a display region of a light-emitting display unit as shown in FIG. 1B, the embodiment of the present disclosure can design the flat portion to be slightly smaller in the process of forming the organic layer by the inkjet printing method, that is, at this time, the flat portion covers only the intermediate region of the display region, and the edge region of the display region is covered by the slope portion of the organic layer. Then, the flat portion of the organic layer is heated so that the organic material included in the flat portion spontaneously flows to the position where the slope portion is located, the height difference between the partial slope portion close to the flat portion and the flat portion is compensated, the partial slope portion covering the edge of the display region is converted into a portion of the flat portion, thereby increasing the size of the flat portion in a direction parallel to the substrate and decreasing the climbing distance of the slope portion. After heating the organic layer, the flat portion can completely cover the display region, which can effectively prevent the display unevenness (display Mura) caused by the unevenness of the thickness of the organic layer, and thereby facilitating to reduce the thickness of the organic layer while ensuring the thickness uniformity of the organic layer. In addition, relative to the case shown in FIG. 1B, the size of the position where the slope portion of the organic layer is located is reduced, that is, the climbing distance of the slope portion is shortened, and therefore, the margin that needs to be leaved for the slope portion in the frame is reduced, so the design of a narrow frame can be achieved.

For example, as shown in FIG. 3B, the display substrate further comprises a barrier dam 213 located outside the display region 211, and the barrier dam 213 is located on a side of the slope portion 112 away from the flat portion 111.

For example, as shown in FIG. 3B, the flat portion 111 can be heated by the heat source 120. For example, a distance between an edge of the slope portion 112 close to the barrier dam 213 and the barrier dam 213 is L3, the climbing distance of the slope portion 112 is L1, and a distance between an end of a heating region of the organic layer which is heated by the heat source 120 close to the barrier dam 213 and the barrier dam 213 is L4, L4≥L1+L3. That is, an orthographic projection of the heating region of the organic layer which is heated by the heat source 120 on the base substrate 200 is located within an orthographic projection of the flat portion 111 on the base substrate 200, so that the heat source 120 only heats the flat portion 111, and the surface tension of the organic material included in the flat portion 111 is lowered. That is, the surface tension of the organic material included the flat portion 111 is lower than the surface tension of the organic material included in the slope portion 112, so that the organic material included the flat portion 111 spontaneously flows to the position where the slope portion 112 is located.

For example, in the embodiment of the present disclosure, a temperature for heating the flat portion 111 is not more than 85° C., to prevent an excessively high heating temperature from affecting the film layer in the light-emitting display unit 212.

In this embodiment, the organic material can be heated while spraying the organic material on the side of the light-emitting display unit away from the substrate by using an inkjet printing method, that is, the organic material is heated during the spraying process before a solidification process is performed on the organic material, to cause the organic material located in the intermediate region of the display region to flow toward the edge region to form the organic layer shown in FIG. 3C, and this process saves process steps and process chambers. The embodiment is not limited thereto, and the organic layer shown in FIG. 3B may be sprayed first, and then the flat portion of the organic layer is heated to form the organic layer shown in FIG. 3C, as long as the flat portion is heated before the organic material is solidified to improve the leveling property of the organic material.

Another embodiment of the present disclosure provides a display substrate, and the display substrate is a display substrate shown in FIG. 3C which is formed by the manufacturing method of the display substrate shown in FIGS. 3A to 3C. The display substrate provided by this embodiment can not only achieve a narrow frame design, but also reduce the probability of occurrence of display unevenness, and also facilitate the thinning of the organic layer in the thin film encapsulation layer, thereby facilitating the bending property of the display device including the display substrate.

Another embodiment of the present disclosure provides a display for manufacturing a thin film encapsulation organic layer of the display substrate shown in FIG. 3C. FIG. 4 is a partial schematic structural diagram of a device for manufacturing a display substrate according to an embodiment of the present disclosure. As shown in FIG. 4, the device for manufacturing the display substrate comprises: an abutment 300 configured to support the base substrate 200, and a heating plate 310 on a side of the abutment 300 facing the base substrate 200, and an orthographic projection of the heating plate 310 on the abutment 300 is located within an orthographic projection of the flat portion 111 before being heated on the abutment 300. The heating plate provided in this embodiment heats only the flat portion of the organic layer, so that the surface tension of the organic material included in the flat portion can be reduced, the organic material spontaneously flows to the position where the slope portion is located, so that the thickness of a portion of the slope portion close to the flat portion is the same as the thickness of the flat portion to increase the size of the flat portion in the direction parallel to the substrate, thereby reducing the climbing distance of the slope portion.

For example, a material of the heating plate 310 comprises, but is not limited to, a metal material such as copper, aluminum, iron, or the like, and an alloy thereof, and may also comprise an organic conductive material, an inorganic conductive material, or the like.

For example, as shown in FIG. 4, a hole channel 301 is further disposed in the abutment 300, and a wire 302 electrically connected to the heating plate 310 is disposed in the hole channel 301, when the wire 302 is electrified, the heating plate 310 can generate heat, and the temperature rises to heat the flat portion 111. The embodiment is not limited thereto, and a heating rod that is in contact with the heating plate may also be disposed in the hole channel, and the temperature of the heating rod is increased after the heating rod is electrified, thereby raising the temperature of the heating plate.

For example, as shown in FIG. 4, the heating plate 310 is located on a surface of a side of the abutment 300 facing the base substrate 200, and the heating plate 310 is vacuum-adsorbed on the abutment 300. In a case where the base substrate 200 is placed on the abutment 300, the abutment 300 is in contact with the heating plate 310 located on the surface of the abutment 300, in this case, a thickness of the heating plate 310 can be designed to be relatively thin, so that the stability of the base substrate 200 placed on the abutment 300 is not affected. Because the size of the heating plate 310 is smaller than the size of the base substrate 200 in the direction parallel to the abutment 300, a surface of a portion of the base substrate 200 that is not in contact with the heating plate 310 can be vacuum-adsorbed on the abutment 300 to achieve the fixing of the position of the base substrate 200.

In an actual process, the mother board including the plurality of display panels shown in FIG. 1A is generally processed, and therefore, the heating plate can be designed as a template corresponding to the positions of the plurality of display panels to facilitate processing.

The abutment of the inkjet printing device for manufacturing the organic layer in the thin film encapsulation layer provided by the embodiment can effectively improve the leveling property of the organic layer in the process of forming the organic layer, thereby ensuring the consistency of thicknesses of the organic layer respectively located in an intermediate region and an edge region of the display region and reducing the probability of generating the display mura. Moreover, the reduction of the climbing distance of the slope portion of the organic layer can facilitate the thinning of the organic layer, that is, facilitate the bending property of the display device. In addition, the climbing distance of the slope portion is shortened, the margin that needs to be leaved for the slope portion in the frame is reduced, so a design of a narrow frame can be achieved.

The following statements should be noted:

(1) The accompanying drawings involve only the structure(s) in connection with the embodiment(s) of the present disclosure, and other structure(s) can be referred to common design(s).

(2) In a case of no conflict, features in one embodiment or in different embodiments can be combined with each other.

What have been described above are only exemplary implementations of the present disclosure, and are not intended to limit the protection scope of the present disclosure, and the protection scope of the present disclosure is determined by the appended claims.

What is claimed is:

1. A manufacturing method of a film layer, comprising:
forming an organic layer on a substrate, wherein the organic layer comprises a flat portion and a slope portion around the flat portion; and
heating the flat portion to cause a material of the flat portion to flow toward the slope portion, such that a thickness of a portion of the slope portion close to the flat portion is identical to a thickness of the flat portion to increase a size of the flat portion in a direction parallel to the substrate.

2. The manufacturing method of the film layer according to claim 1, wherein the organic layer has a material that is capable of flowing in a heated state.

3. The manufacturing method of the film layer according to claim 2, wherein the organic layer is formed by an inkjet printing method.

4. The manufacturing method of the film layer according to claim 3, wherein forming the organic layer by the inkjet printing method comprises:
printing an organic material on the substrate, and the flat portion and the slope portion being formed during a leveling process of the organic material.

5. The manufacturing method of the film layer according to claim 1, wherein heating the flat portion comprises:
heating only the flat portion, or heating the flat portion at a temperature higher than a temperature at which the slope portion is heated.

6. The manufacturing method of the film layer according to claim 5, wherein heating only the flat portion comprises:
heating the flat portion by a heat source, wherein an orthographic projection of a region of the organic layer heated by the heat source on the substrate is located in an orthographic projection of the flat portion before being heated on the substrate.

7. The manufacturing method of the film layer according to claim 1, wherein a thickness of the flat portion is uniform.

8. The manufacturing method of the film layer according to claim 1, wherein during heating, a size of an orthographic projection of the organic layer on the substrate does not change.

9. A manufacturing method of a display substrate, comprising:
forming a plurality of light-emitting display units on a base substrate; and
forming the organic layer by using the manufacturing method according to claim 1 on a side of the plurality of light-emitting display units away from the base substrate.

10. The manufacturing method of the display substrate according to claim 9, wherein the organic layer is a thin film encapsulation layer.

11. The manufacturing method of the display substrate according to claim 10, wherein the display substrate comprises a display region and a peripheral region surrounding the display region, and the plurality of light-emitting display units are formed in the display region,
before heating, an orthographic projection of the flat portion on the base substrate is located within an orthographic projection of the display region on the base substrate, and an orthographic projection of the slope portion on the base substrate overlaps with the orthographic projection of the display region on the base substrate;
after heating, the orthographic projection of the slope portion on the base substrate does not overlap with the orthographic projection of the display region on the base substrate.

12. The manufacturing method of the display substrate according to claim 10, wherein a temperature for heating the flat portion is not more than 85° C.

13. A display substrate formed by the manufacturing method of the display substrate according to claim 9.

14. A device for manufacturing the display substrate according to claim 13, comprising:
an abutment, configured to support the base substrate; and
a heating plate, on a side of the abutment facing the base substrate, wherein an orthographic projection of the heating plate on the abutment is located within an orthographic projection of the flat portion before being heated on the abutment.

15. The device according to claim 14, wherein the heating plate and the base substrate are vacuum-adsorbed on a surface of the abutment.
